(19) United States
(12) Patent Application Publication
(10) Pub. No.: US 2008/0023779 A1
(43) Pub. Date: Jan. 31, 2008

(54) Photoelectric conversion element

(75) Inventor: Tatsuya Usuki, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/889,365

(22) Filed: Aug. 13, 2007

Related U.S. Application Data
(63) Continuation of application No. PCT/JP05/02281, filed on Feb. 15, 2005.

(51) Int. Cl. H01L 27/14; H01L 29/06

(52) U.S. Cl. 257/431; 257/15

(57) ABSTRACT

In a photoelectric conversion element which generates electrical signals upon the incidence of light, a superlattice structure having a metal layer or metal silicide layer and a polysilicon layer is formed on a silicon substrate, the photoelectric conversion element has a three-terminal structure in which the metal layer or metal silicide layer at the upper edge of the superlattice structure is the first terminal, the lower edge of the superlattice structure is the second terminal, and the silicon substrate is the third terminal. In this photoelectric conversion element, for example, a superlattice structure, in which metal layers (or metal silicide layers) of thickness approximately several nm and polysilicon layers which are at least thicker than this are formed in alternation in a multilayer structure, is formed on a silicon semiconductor substrate. And carriers exited in the metal layer due to incident light are released to the polysilicon layers and reach to the third terminal as hot carriers to generate electric signal.

### CROSS REFERENCE TO RELATED APPLICATIONS

This application is a continuation of International Application No. PCT/JP2005/2281, filed on Feb. 15, 2005, now pending, herein incorporated by reference.

### TECHNICAL FIELD

This invention relates to a photoreceiving element or other photoelectric conversion element, and in particular relates to a photoelectric conversion element capable of converting optical signals in wavelength bands suitable for optical fiber transmission into electrical signals, and which can be fabricated using silicon processes.

### BACKGROUND ART

Optical signals suitable for optical fiber transmission have wavelengths in the band from 1.3 to 1.55 μm, longer than the wavelengths of visible light, and lower energy accordingly. Consequently the optical signals used in optical transmission cannot excite carriers exceeding the band gap of silicon semiconductors, so that photoreceiver elements employing silicon semiconductors have not been realized for use in optical communication. Photoreceiver elements for optical transmission in the prior art have generally employed compound semiconductors, with band gaps smaller than that of silicon, due to the circumstances of the longer-wavelength band and lower energies used. Photoreceiver elements employing such compound semiconductors cannot be combined with integrated circuits manufactured using silicon processes, so that fabrication on a single chip is not possible. Modulator elements which insert transmission signals into laser light can be manufactured using silicon processes, but as explained above, there are no photoreceivers fabricated using silicon processes, and so single-chip silicon devices have not been realized.

On the other hand, infrared sensors employing silicon semiconductors have been proposed, as for example in “Trends in Development of Infrared Solid-State Imaging Devices”, Sensor Technology, March 1987 (Vol. 7 No. 3). Infrared rays have longer wavelengths and lower energy than visible light, and has problems similar to those for optical signals in optical communication.

FIG. 1 shows the energy band diagram for an infrared sensor using a silicon semiconductor of the prior art. In this infrared sensor, platinum silicide PtSi, which is a thin metal electrode, is formed on a P-type silicon semiconductor substrate Si-Sub, and a Schottky barrier φb is formed between the silicon semiconductor Si-Sub and the metal electrode PtSi. Upon incidence of infrared rays, electron-hole pairs are formed within the metal electrode, and these move randomly within the metal electrode; of the holes which reach the semiconductor-metal interface, those holes having energy sufficient to cross the Schottky barrier φb are released into the silicon semiconductor Si-Sub and become a photocurrent. In the diagram, Ec is the bottom of the conduction band, Ev is the top of the valence band, and Ef is the Fermi energy level.

In this infrared sensor, by forming a metal electrode to be thin, the quantum efficiency, indicating the efficiency with which holes excited by incident infrared rays are released to the silicon semiconductor side, can be increased. However, this quantum efficiency is at most approximately 5% in the wavelength band for optical communications, and while suitable for specialized applications such as in infrared sensors, is not suited to photoreceivers for optical communication, which receive extremely weak optical signals.

Japanese Patent Publication No. 8-31619 describes that a semiconductor layer has a junction with a metal electrode is formed as a silicon semiconductor superlattice structure in order to arbitrarily control the height of the Schottky barrier in the above infrared sensor, utilizing the quantum levels generated by the superlattice structure. In this case also, the quantum efficiency cannot be raised very high.

Japanese Patent Laid-open No. 10-65203 describes an avalanche photodiode configured by providing a silicon superlattice structure between an anode and a cathode. However, a silicon semiconductor is used in an APD for visible light, and use as a photoreceiver element in optical communication is not possible.

As a photoreceiver element for use with light in the wavelength band of optical communication, a metal electrode can be formed on the silicon semiconductor described in Japanese Patent Publication No. 8-31619, and the Schottky barrier at the interface thereof can be utilized. However, because the quantum efficiency, which is the proportion of carriers generated to the light quantity, is only about 5% as explained above, such a device is not appropriate for use as a photoreceiver element which detects extremely weak optical signals in optical communication.

Hence an object of this invention is to provide a photoelectric conversion element which can be formed using silicon processes, and which can detect extremely weak optical signals in optical communication.

### DISCLOSURE OF THE INVENTION

In order to attain the above object, according to a first aspect of the invention, in a photoelectric conversion element which generates electrical signals upon the incidence of light, a superlattice structure having a metal layer or metal silicide layer and a polysilicon layer is formed on a silicon substrate, the photoelectric conversion element has a three-terminal structure in which the metal layer or metal silicide layer at the upper edge of the superlattice structure is the first terminal, the lower edge of the superlattice structure is the second terminal, and the silicon substrate is the third terminal. In this photoelectric conversion element, for example, a superlattice structure, in which metal layers (or metal silicide layers) of thickness approximately several nm and polysilicon layers which are at least thicker than this are formed in alternation in a multilayer structure, is formed on a silicon semiconductor substrate.

By means of the above configuration, hot carriers excited within the plurality of metal layers (or metal silicide layers) by incident light are released into the polysilicon layers and become electrical signals. By employing a superlattice structure, the probability of hot carriers excited in the plurality of thin metal layers (or metal silicide layers) being released into adjacent polysilicon layers is increased, and the quantum efficiency can be raised. However, there exist numerous interface states within the polysilicon layers of the superlattice structure, and so a large leak current due to the tunneling effect from a first terminal toward a second terminal exists. But, this leak current flows to the second terminal on the lower-edge side of the superlattice structure, and so does not give rise to a dark current. The current converted from the incident light is then detected with high sensitivity on the side of the third terminal.

In a preferred embodiment of the above first aspect, the metal layers (or metal silicide layers) comprise platinum layers (or silicide layers thereof), and upon light incidence, hot holes are released into the polysilicon layers. When platinum silicide layers are layered with polysilicon layers, the Schottky barrier on the valence-band side is lowered, and light in the wavelength band used for optical communication causes hot holes to cross the Schottky barrier. Hot holes released in this way into polysilicon layers are accelerated by the electric field and have high energy, and so cross the second terminal region and become a current at the third terminal. In the superlattice structure region between the first and second terminals, new hot holes are excited from platinum silicide layers, and amplification action is anticipated.

In a preferred embodiment of the above first aspect, the metal layers (or metal silicide layers) comprise rare-earth metal layers (or silicide layers thereof), and upon light incidence, hot electrons are released into the polysilicon layers. When rare-earth metal silicide layers are layered with polysilicon layers, the Schottky barrier on the conduction-band side is lowered, and light in the wavelength band used for optical communication causes hot electrons to cross the Schottky barrier. Because the hot electrons have high energy, they cross the second terminal region and become a current at the third terminal. Further, the ionization rate for electrons is high in silicon semiconductors, and due to an avalanche phenomenon in which electrons are newly excited in the silicon substrate, amplification action occurs, and electrical signals can be created with higher sensitivity.

In order to attain the above object, according to a second aspect of the invention, a photoelectric conversion element which generates electrical signals upon the incidence of light has a silicon substrate on which is formed a collector electrode, a base electrode of a metal layer or metal silicide layer formed on the silicon substrate, a polysilicon layer formed on the base electrode, and an emitter electrode of a metal layer or metal silicide layer formed on the polysilicon layer; and a bias voltage is applied across the base and emitter electrodes.

By means of the above configuration, hot carriers excited at the emitter electrode and base electrode are released into the silicon substrate, and a collector current occurs. Further, the leak current within the polysilicon layer between the emitter and base electrodes is absorbed at the base electrode as a base current. Hence a photodetection current can be captured as a collector current with only a small dark current.

By means of this invention, a photoelectric conversion element can be provided with high sensitivity, and in which hot carriers form the detection current with higher quantum efficiency.

### BRIEF DESCRIPTION OF THE DRAWINGS

FIG. 1 is an energy band diagram of an infrared sensor using a silicon semiconductor in the prior art;

FIG. 2 is a cross-sectional view of the photoelectric conversion element in an embodiment of the invention;

FIG. 3 is the band diagram of the photoelectric conversion element in an embodiment of the invention;

FIG. 4 is another band diagram of the photoelectric conversion element in an embodiment of the invention; and

FIG. 5 is a cross-sectional view and band diagram of the photoelectric conversion element in an embodiment of the invention.

Si-Sub: Silicon semiconductor layer, Silicon semiconductor substrate

Msi: Metal layer or Metal silicide layer

Psi: Polysilicon layer

E: Emitter electrode, First electrode

B: Base electrode, Second electrode

C: Collector electrode, Third electrode

### BEST MODE FOR CARRYING OUT THE INVENTION

Below, embodiments of the invention are explained referring to the drawings. However, the technical scope of the invention is not limited to these embodiments, but extends to the inventions described in the Claims, and to inventions equivalent thereto.

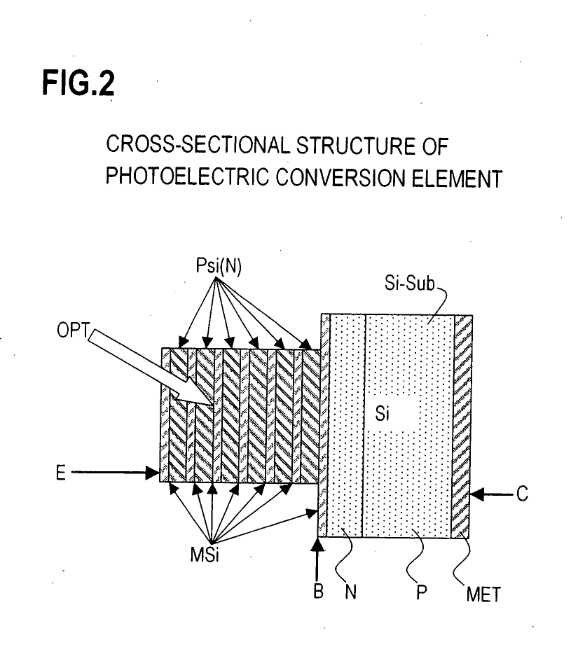

FIG. 2 is a cross-sectional view of the photoelectric conversion element of one embodiment. The photoelectric conversion element is a phototransistor having an emitter E, collector C, and base B. In the photoelectric conversion element, a superlattice structure of a plurality of metal layers (or metal silicide layers) MSi and a plurality of polysilicon layers PSi is formed on a substrate Si-Sub which is a silicon semiconductor layer. The metal layers (or metal silicide layers) (hereafter simply called metal silicide layers) MSi are thin layers of thickness approximately several nm (for example, 10 nm or less); the polysilicon layers PSi formed therebetween are at least thicker than the metal silicide layers MSi, and are thin layers of thickness for example approximately 10 to 50 nm. The metal silicide layer MSi at the upper edge of the superlattice structure is the emitter electrode E, and the metal silicide layer MSi at the lower edge (on the silicon substrate side) is the base electrode B. An electrode layer MET is formed on the silicon semiconductor substrate Si-Sub to serve as the collector electrode C.

The polysilicon layers PSi of the superlattice structure are N-doped semiconductor layers. The surface side of the Si-Sub substrate which is a silicon semiconductor layer is also an N-doped region N, on top of which the metal silicide layer MSi serving as the base electrode B is formed. The silicon substrate Si-Sub on the side of the collector electrode MET is a P-doped region P.

With a prescribed bias voltage is applied across emitter and base, and a prescribed bias voltage also applied across emitter and collector, incident light OPT is incident on the superlattice structure as indicated by an arrow. This incident light OPT excites carriers within the plurality of metal silicide layers MSi. Because the metal silicide layers MSi are extremely thin, with a thickness of several nm, when the excited carriers move within the layers many carriers cross the Schottky barriers with adjacent polysilicon layers PSi, and are released as hot carriers. These hot carriers have high kinetic energy, and jump across the base region B to become a collector current. The principle of operation is explained below based on band diagrams.

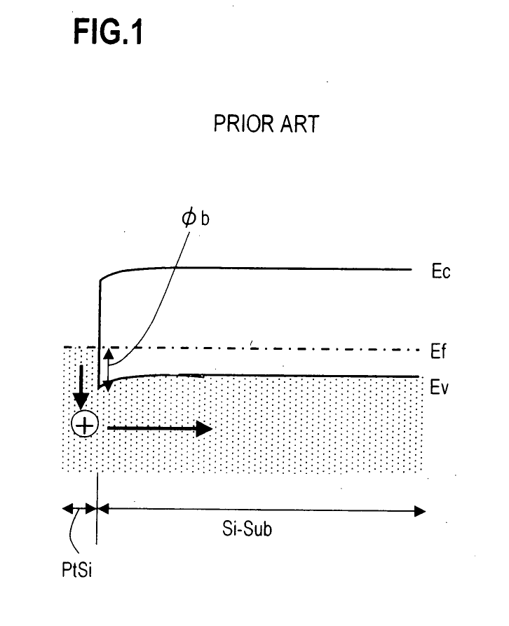

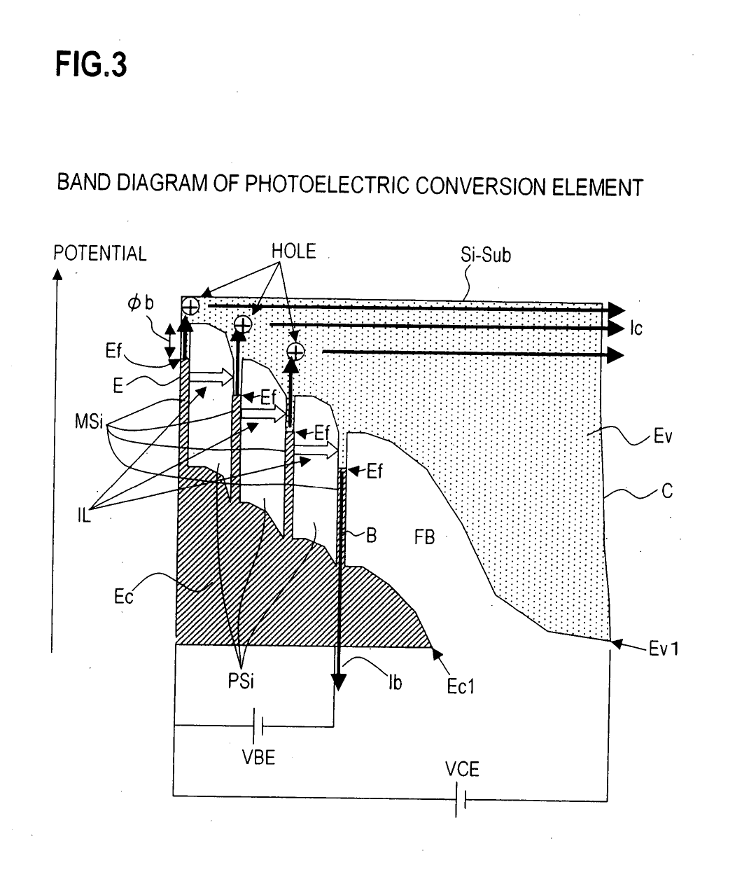

FIG. 3 is a band diagram of the photoelectric conversion element of this embodiment. In this embodiment, the band diagram is for the case in which the metal silicide layers MSi are platinum silicide layers. The band diagram of FIG. 3 shows not energy levels, but the inverse of this, potential levels, in the vertical direction. That is, the vertical direction is inverted from that of a normal energy band diagram, and is also inverted vertically relative to FIG. 1. Hence in the band diagram of FIG. 3, the valence band Ev is on the upper side, the conduction band Ec is on the lower side, and the forbidden band FB is positioned therebetween. Ev1 is the upper edge of the valence band Ev, and Ec1 is the bottom of the conduction band Ec.

From the right side in FIG. 3, the band structures of the silicon substrate Si-Sub and of the superlattice structure of metal silicide layers MSi and polysilicon layers PSi are shown. In each of the metal silicide layers MSi, the Fermi level Ef is shown. When the metal silicide layers MSi are platinum silicide layers, the barrier heights φb of polysilicon layers PSi relative to the Fermi levels Ef in the metal silicide layers MSi are lower on the side of the valence band Ev than on the side of the conduction band Ec toward. This is uniquely determined from the work function of the platinum silicide layer.

With a base-emitter voltage VBE applied across the emitter E and base B, and a collector-emitter voltage VCE applied across the collector C and emitter E, when light is incident from the emitter side on the superlattice structure, the energy of the incident light causes excitation of electron-hole carrier pairs in the metal silicide layers MSi. Many of these holes HOLE are excited as indicated by the upward-directed arrow in the metal silicide layers MSi in FIG. 3, and have an energy level exceeding the Schottky barrier φb with the adjacent polysilicon layers PSi, therefore, holes are released into the polysilicon layers PSi. The released holes HOLE are accelerated by the electric field due to the base-emitter voltage, becoming hot holes having high energy levels, and jump across the base electrode B to flow into the collector C and become the collector current Ic. Moreover, first, the metal silicide layers MSi are extremely thin at only several nm, so that many of the holes excited therein move to polysilicon layers within the mean free paths thereof; and second, the superlattice structure has a plurality of metal silicide layers MSi, so that more holes become hot holes. Hence the quantum efficiency, which is the proportion of hot holes occurring to the number of incident photons, is high, and a large collector current Ic can be generated.

However, because the polysilicon layers PSi forming the superlattice structure have a polycrystalline structure, they have numerous interface states. As a result, due to application of an emitter-base bias, numerous holes flow due to the tunneling effect from the emitter electrode E toward the base electrode as indicated by the white arrows, becoming a leak current IL. However, the holes which are the cause of this leak current are cold holes which do not have high energy levels compared with excited hot holes, and so nearly all are absorbed at the base electrode B as the base current Ib. Consequently the leak current IL is not included in the collector current Ic, so does not become a large dark current. In this way, in the photoelectric conversion element of this embodiment, by employing a three-terminal structure the problem of dark currents accompanying a superlattice structure is resolved.

Further, a hot hole amplification effect can be expected between emitter and base due to the avalanche phenomenon in which new hot holes are excited at the platinum silicide layers by existing hot holes. Through this amplification action, a large detection current can be generated from a minute optical signal, similarly to an APD (avalanche photodiode).

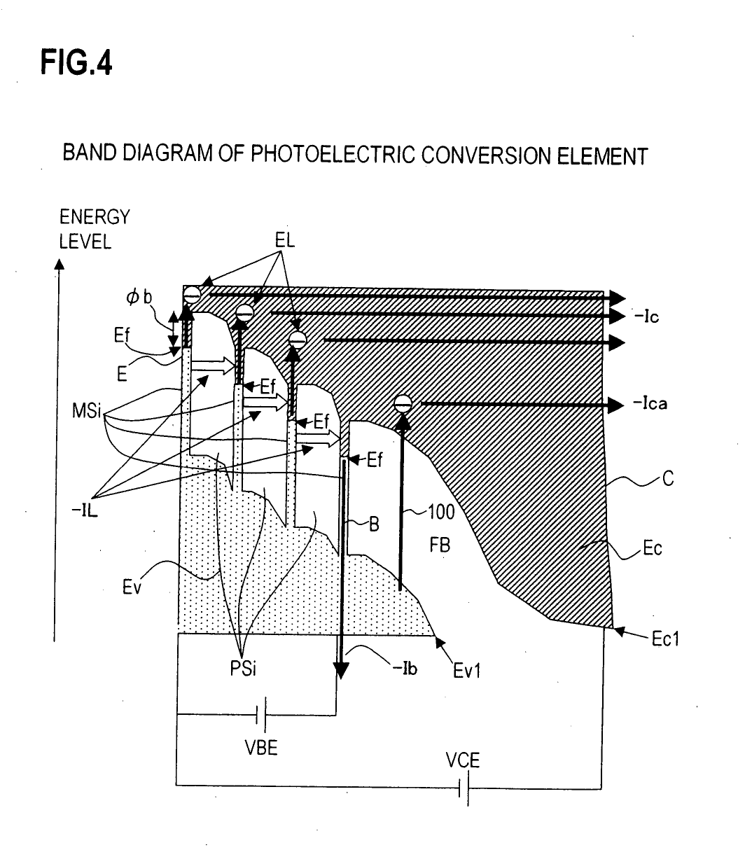

FIG. 4 is another band diagram of the photoelectric conversion element of an embodiment. This is a band diagram for an embodiment in which the metal silicide layers MSi are rare-earth metal silicide layers of erbium Er or similar. In this band diagram, the vertical direction indicates the energy level, in the same manner as in FIG. 1 and inverted from that of FIG. 3. Hence the conduction band Ec is on the upper side, and the valence band Ev is positioned on the lower side.

In the case of erbium or other rare-earth metal silicide layers, the energy barrier with polysilicon layers PSi is lower on the side of the conduction band Ec. Hence of the electrons and holes excited by incident light, the electrons EL cross the energy barrier φb with the conduction band Ec and are released on the side of the polysilicon layers PSi. A base-emitter voltage VBE is applied across the emitter E and base B, and due to the electric field resulting from this bias voltage, the released electrons EL are accelerated, becoming hot electrons and crossing the base region to flow into the collection region and become the collector current Ic. This principle is the same as in FIG. 3.

In the case of this example, the polysilicon layers PSi are doped with P-type impurities, the base electrode side of the silicon substrate Si-Sub is doped with P-type impurities, and the collector electrode side is doped with N-type impurities. That is, in the case of erbium or another rare-earth metal, electrons are easily released, and so it is desirable that the polysilicon layers and the base electrode side of the semiconductor layer be P type, and that the collector side be N type.

In this case also, the rare-earth metal silicide layers MSi are extremely thin, at several nm, and so many of the excited electrons move to the adjacent polysilicon layers PSi. Further, because numerous rare-earth metal silicide layers MSi are provided, the number of excited electrons is also large, and so the collector current Ic is large.

Through movement of hot electrons EL in the silicon semiconductor layer Si-Sub, because of the property of high ionization by electrons of the silicon semiconductor, new electrons are excited (100 in the figure) within the silicon semiconductor Si-Sub, and an electron avalanche phenomenon occurs. This avalanche phenomenon has already been confirmed in visible-light APDs, and reliably occurs. As a result of this avalanche phenomenon, hot electrons are amplified and the collector current Ic further increases. Hence in the case of FIG. 4, the quantum efficiency is higher.

In the example of FIG. 4 also, due to interface states within polysilicon layers PSi, electrons move by the tunneling effect in the direction of the white arrows, and a leak current from base to emitter occurs. However, electrons moving due to the tunneling effect do not have a high potential energy with respect to the base electrode, and so are absorbed in the base current Ib. Hence inclusion in the collector current Ic of the base-emitter leak current as a dark current is avoided.

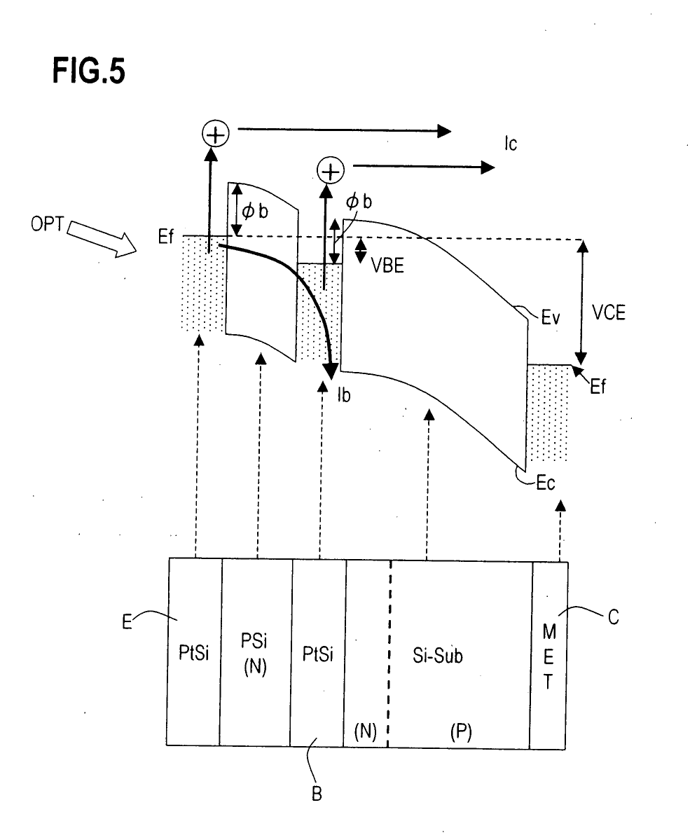

FIG. 5 is a cross-sectional view and band diagram of a photoelectric conversion element of the embodiment. In this example, the superlattice structure between the emitter and base has a three-layer structure, comprising a platinum silicide layer PtSi which is an emitter electrode E, a polysilicon layer PSi, and a platinum silicide layer PtSi which is a base electrode B. The configuration of the silicon substrate Si-Sub on which the collector electrode C is formed is the same as in the examples of FIG. 2 and FIG. 3. If the superlattice structure has only a three-layer structure, the number of metal silicide layers in which hot carriers are excited is reduced, but in principle, because there are a plurality of metal silicide layers and the structure is a three-terminal structure, a photoelectric conversion element is obtained with high quantum efficiency is obtained and minimal dark current.

The principle of operation is the same as in FIG. 3; holes in the platinum silicide layers PtSi which have been excited by incident light cross the schottky barrier φb, and are released into the adjacent polysilicon layer PSi and silicon substrate Si-Sub. The released holes are accelerated by the bias electric field to become hot holes, which reach the collector electrode. This becomes the collector current Ic detected upon light incidence. On the other hand, a leak current due to interface states in the polysilicon layer PSi occurs between the base and emitter, but because of the low potential energy, the current is absorbed as a base current Ib. In this way, by adopting a plurality of metal silicide layers which form Schottky barriers with the silicon layers and a three-terminal structure, a photoelectric conversion element can be provided with high quantum efficiency and small dark current.

The above embodiments were explains as examples of superlattice structures employing platinum silicide layers and polysilicon layers, and of superlattice structures employing rare-earth metal silicide layers and polysilicon layers. This invention is not limited to these materials, and in place of platinum, nickel or palladium can be employed. In addition, application to superlattice structures employing layers of titanium, cobalt, or tungsten, or silicide layers of these, with polysilicon layers, and to superlattice structures employing P-type germanium layers or other impurity-doped semiconductor layers with polysilicon layers (however, with platinum silicide layers for the emitter and base), is also possible.

In FIG. 2 and FIG. 5, a collector electrode is formed on the rear-face side of the silicon semiconductor substrate Si-Sub; but the superlattice structure and base electrode may have a mesa structure, and the collector electrode may be formed on the top-face side of the silicon semiconductor substrate. In this case, the collector region is formed as a P-type well region.

### INDUSTRIAL APPLICABILITY

A photoelectric conversion element can be provided which can be manufactured using silicon processes, and which can be employed in optical communications in the wavelength band (1.3 to 1.55 μm) used for optical communication by optical fiber.

1. A photoelectric conversion element, which generates electric signals in response to incident light, comprising:
a silicon semiconductor layer; and
a superlattice structure, formed on said silicon semiconductor layer, having layered metal layers or metal silicide layers and polysilicon layers;
wherein the metal layer or metal silicide layer at the upper edge of said superlattice structure is a first terminal, the lower edge of said superlattice structure is a second terminal, and said silicon semiconductor layer is a third terminal.

2. The photoelectric conversion element according to claim 1, wherein said metal layers or metal silicide layers comprise metal layers of platinum, palladium, or nickel, or silicide layers thereof.

3. The photoelectric conversion element according to claim 2, wherein said polysilicon layers are doped with N-type impurities, and said silicon semiconductor layer is doped with N-type impurities in the region in which said second terminal is formed and is doped with P-type impurities in the region in which said third terminal is formed.

4. The photoelectric conversion element according to claim 1, wherein said metal layers or metal silicide layers comprise metal layers of a rare-earth metal, or silicide layers thereof.

5. The photoelectric conversion element according to claim 4, wherein said polysilicon layers are doped with P-type impurities, and said silicon semiconductor layer is doped with P-type impurities in the region in which said second terminal is formed and is doped with N-type impurities in the region in which said third terminal is formed.

6. The photoelectric conversion element according to claim 1, wherein said metal layers or metal silicide layers comprise metal layers of titanium, tungsten or cobalt, or silicide layers thereof.

7. The photoelectric conversion element according to claim 1, wherein a first bias voltage is applied across said first terminal and second terminal, and a second bias voltage is applied across said first terminal and third terminal.

8. The photoelectric conversion element according to claim 1, wherein said metal layers or metal silicide layers have a thickness of 10 nm or less, and said polysilicon layers have a thickness that is greater than that of said metal layers or metal silicide layers.

9. The photoelectric conversion element according to claim 1, wherein said metal layers or metal silicide layers have a thickness of 10 nm or less, and said polysilicon layers have a thickness of 10 nm to 50 nm.

10. A photoelectric conversion element, which generates electric signals in response to incident light, comprising:
a silicon semiconductor layer on which is formed a collector electrode;
a base electrode having a metal layer or metal silicide layer, formed on said silicon semiconductor layer;
a polysilicon layer, formed on said base electrode; and
an emitter electrode having a metal layer or metal silicide layer, formed on said polysilicon layer.

11. The photoelectric conversion element according to claim 10, wherein said metal layer or metal silicide layer comprises a metal layer of platinum, palladium, nickel, a rare-earth metal, tungsten, cobalt, or titanium, or a silicide layer thereof.

12. A photoelectric conversion element according to claim 10, further comprising a superlattice structure, in which polysilicon layers and metal layers or metal silicide layers are layered in order, between said base electrode and polysilicon layer.

13. The photoelectric conversion element according to claim 12, wherein a first bias voltage is applied across said base and emitter electrodes, and a second bias voltage is applied across said collector and emitter electrodes.

14. A photoelectric conversion element, which generates electric signals in response to incident light, comprising:
a silicon semiconductor layer on which is formed a collector electrode;
a base electrode having a metal layer or metal silicide layer, formed on said silicon semiconductor layer;
a superlattice structure having layered polysilicon layers and impurity-doped semiconductor layers, formed on said base electrode; and,
an emitter electrode having a metal layer or metal silicide layer, formed on the polysilicon layer at the upper end of said superlattice structure.
